(19) United States
(12) Patent Application Publication
(10) Pub. No.: US 2020/0402845 A1
(43) Pub. Date: Dec. 24, 2020

(54) SEMICONDUCTOR STRUCTURE AND FORMATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Liu JIQUAN, SHANGHAI (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 16/863,007

(22) Filed: Apr. 30, 2020

(30) Foreign Application Priority Data
Jun. 18, 2019 (CN) 201910527770.4

(51) Int. Cl. H01L 21/768; H01L 23/532

(52) U.S. Cl. CPC H01L 21/76873; H01L 23/53238; H01L 21/76846; H01L 21/76802

(57) ABSTRACT

A semiconductor structure and a formation method thereof are provided. A form of the formation method of the semiconductor structure includes: providing a substrate; forming a dielectric layer on the substrate; forming a contact hole in the dielectric layer; forming a seed layer on a bottom and a sidewall of the contact hole, where a thickness of the seed layer on the bottom of the contact hole is greater than a thickness of the seed layer on the sidewall of the contact hole; and forming a conductive plug in the contact hole. The semiconductor structure includes: a substrate; a dielectric layer located on the substrate; a contact hole located in the dielectric layer; a seed layer located on a bottom and a sidewall of the contact hole, where a thickness of the seed layer on the bottom of the contact hole is greater than a thickness of the seed layer on the sidewall of the contact hole; and a conductive plug located in the contact hole. The present disclosure can improve the reliability of an electrical connection of the conductive plug.

### RELATED APPLICATIONS

The present application claims priority to Chinese Patent Appln. No. 201910527770.4, filed Jun. 18, 2019, the entire disclosure of which is hereby incorporated by reference.

### BACKGROUND

### Technical Field

Embodiments and implementations of the present disclosure relate to the field of semiconductor manufacturing, and in particular, to a semiconductor structure and a formation method thereof.

### Related Art

Main semiconductor devices of integrated circuits, especially very-large-scale integrated circuits, are metal-oxide-semiconductor field effect transistors (MOS transistors). With the development trend of the very-large-scale integrated circuits, integrated circuits are becoming more and more complex, and semiconductor device technology nodes are continuously decreasing. When a size of a semiconductor device is reduced to a certain extent, various secondary effects occur one after another due to physical limits of the semiconductor device such as large leakage current. In order to improve upon the problem of the leakage current, a high-k gate dielectric material is mainly used to replace a conventional silicon dioxide gate dielectric material at present, and metal is used as a gate electrode, so as to avoid a Fermi level pinning effect and a boron penetration effect between a high-k material and a conventional gate electrode material.

Moreover, with the development trend of the very-large-scale integrated circuits, more and more components are included. For example, a contact hole process has become an indispensable process step in the manufacture of MOS transistors. A contact hole plug is an important medium for connecting an active region of a MOS transistor to a rear-end metal layer and finally connecting an external circuit. The formation quality of the contact hole plug directly affects the device performance and the product yield.

The development of the process places higher demands on the reliability of an electrical connection between the contact hole plug and the external circuit.

### SUMMARY

Embodiments and implementations of the present disclosure are directed to a semiconductor structure and a formation method thereof, which improve a reliability of an electrical connection.

To address the aforementioned problem, the present disclosure provides a formation method of a semiconductor structure. In one form, the formation method includes: providing a substrate; forming a dielectric layer on the substrate; forming a contact hole in the dielectric layer; forming a seed layer on a bottom and a sidewall of the contact hole, where a thickness of the seed layer on the bottom of the contact hole is greater than a thickness of the seed layer on the sidewall of the contact hole; and forming a conductive plug in the contact hole.

In some implementations, the step of forming a seed layer includes: forming a first seed layer on a bottom and a sidewall of the contact hole using a chemical vapor deposition process; and forming a second seed layer on the first seed layer using a radio frequency physical vapor deposition process.

In some implementations, the radio frequency physical vapor deposition process has a power of 2 KW to 4 KW and a frequency in the range of 2 MHZ to 40 MHZ.

In some implementations, the step of forming a seed layer includes: forming a first seed layer on a bottom and a sidewall of the contact hole using a chemical vapor deposition process; and forming a second seed layer on the first seed layer using a direct current physical vapor deposition process, wherein the direct current physical vapor deposition process has a power in a range of 5 KW to 15 KW.

In some implementations, the thickness of the second seed layer on the bottom of the contact hole is at least twice the thickness of the second seed layer on the sidewall.

In some implementations, the first seed layer has a thickness in a range of 1-5 nm.

In some implementations, the second seed layer has a thickness in a range of 2-8 nm.

In some implementations, a material of the seed layer is cobalt or ruthenium.

In some implementations, a conductive plug is formed in the contact hole by an electroplating process.

In some implementations, a material of the conductive plug is copper.

In some implementations, the formation method further includes: forming, after forming the contact hole and before forming the seed layer, a diffusion barrier layer on the bottom and sidewall of the contact hole.

In some implementations, the diffusion barrier layer has a thickness in a range of 1-5 nm.

The present disclosure also provides a semiconductor structure. In one form, the semiconductor structure includes: a substrate; a dielectric layer located on the substrate; a contact hole located in the dielectric layer; a seed layer located on a bottom and a sidewall of the contact hole, where a thickness of the seed layer on the bottom of the contact hole is greater than a thickness of the seed layer on the sidewall of the contact hole; and a conductive plug located in the contact hole.

In some implementations, the seed layer includes: a first seed layer located on a bottom and a sidewall of the contact hole; and a second seed layer located on the first seed layer, where a thickness of the second seed layer on the bottom of the contact hole is greater than a thickness of the second seed layer on the sidewall of the contact hole.

In some implementations, the thickness of the second seed layer on the bottom of the contact hole is at least twice the thickness of the second seed layer on the sidewall.

In some implementations, the first seed layer has a thickness in a range of 1-5 nm.

In some implementations, the second seed layer has a thickness in a range of 2-8 nm.

In some implementations, a material of the seed layer is cobalt or ruthenium.

In some implementations, a material of the conductive plug is copper.

In some implementations, the semiconductor structure further includes: a diffusion barrier layer located between the bottom of the contact hole or the sidewall of the contact hole and the seed layer.

Compared with the prior art, technical solutions of the embodiments and implementations of the present disclosure have the following advantages:

In embodiments and implementations of the present disclosure, a seed layer is formed on the bottom and sidewall of a contact hole, and the thickness of the seed layer on the bottom of the contact hole is greater than the thickness of the seed layer on the sidewall of the contact hole, so that when a conductive plug is formed in the contact hole, since the thickness of the seed layer on the bottom of the contact hole is large, a conductive material is relatively easy to nucleate on the thicker seed layer. Therefore, the growth rate of the conductive material above the bottom of the contact hole is high, even if an opening of the contact hole is small, the conductive material on the bottom of the contact hole has reached a large thickness before the conductive material contacts the sidewall of the contact hole to seal the opening, thereby achieving complete filling in the contact hole, so that the formation probability of a hole can be reduced, and the formation quality of the conductive plug can be improved, thereby improving the reliability of an electrical connection between the conductive plug and an external circuit.

### BRIEF DESCRIPTION OF THE DRAWINGS

FIG. 1 and FIG. 2 are schematic diagrams of one form of a formation method of a semiconductor structure.

FIG. 3 to FIG. 8 are schematic structural diagrams of various steps of one form of a formation method of a semiconductor structure.

### DETAILED DESCRIPTION

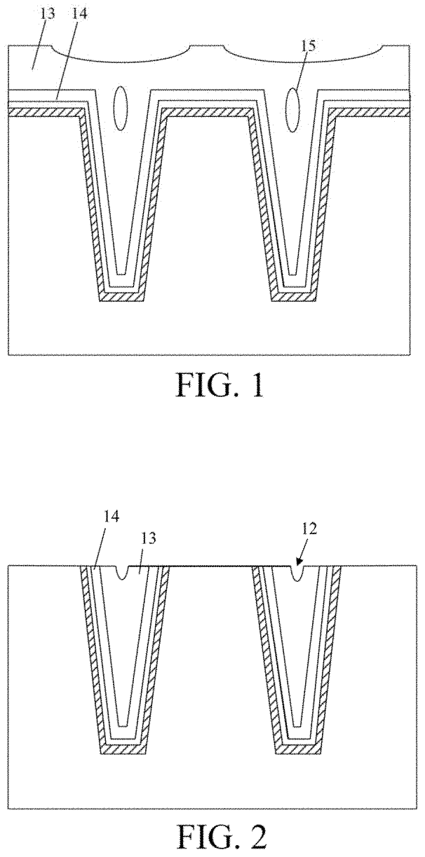

It is known from the background art that a contact hole plug and an external circuit have a problem of low electrical connection reliability. The cause of the problem is illustrated in conjunction with a schematic diagram of a formation method of a semiconductor structure shown in FIG. 1 and FIG. 2.

Referring to FIG. 1, an opening of a contact hole is decreasing in size, and a seed layer 14 is formed on a sidewall and bottom of the contact hole. When a conductive material 13 is filled into the contact hole by electroplating, while the conductive material on the bottom of the contact hole has not yet grown to the desired thickness, the conductive material on the sidewall of the contact hole has filled the opening of the contact hole, so as to generate a hole 15 at the opening of the contact hole.

Referring to FIG. 2, when the excess conductive material 13 is removed by a planarization process, the conductive material 13 remaining in the contact hole remains as a contact hole plug. Due to the existence of the hole 15, the surface of the contact hole plug formed after the planarization process is formed with a notch 12, so that the appearance quality of the formed contact hole plug is not satisfactory, and the notch 12 is likely to cause a bad contact between the contact hole plug and an external circuit, which affects the reliability of an electrical connection.

To address the aforementioned technical problem, implementations of the present disclosure provide a formation method of a semiconductor structure. In one form, the formation method includes: providing a substrate; forming a dielectric layer on the substrate; forming a contact hole in the dielectric layer; forming a seed layer on a bottom and a sidewall of the contact hole, where a thickness of the seed layer on the bottom of the contact hole is greater than a thickness of the seed layer on the sidewall of the contact hole; and forming a conductive plug in the contact hole.

In some implementations of the present disclosure, the seed layer is formed on the bottom and sidewall of the contact hole, and the thickness of the seed layer on the bottom of the contact hole is greater than the thickness of the seed layer on the sidewall of the contact hole, so that when the conductive plug is formed in the contact hole, since the thickness of the seed layer on the bottom of the contact hole is large, a conductive material is relatively easy to nucleate on the thicker seed layer. Therefore, a growth rate of the conductive material above the bottom of the contact hole is high, even if an opening of the contact hole is small, the conductive material on the bottom of the contact hole has reached a relatively large thickness before the conductive material contacts the sidewall of the contact hole to seal the opening, thereby achieving complete filling in the contact hole, so that the formation probability of a hole can be reduced, and the formation quality of the conductive plug can be improved, thereby improving the reliability of an electrical connection between the conductive plug and an external circuit.

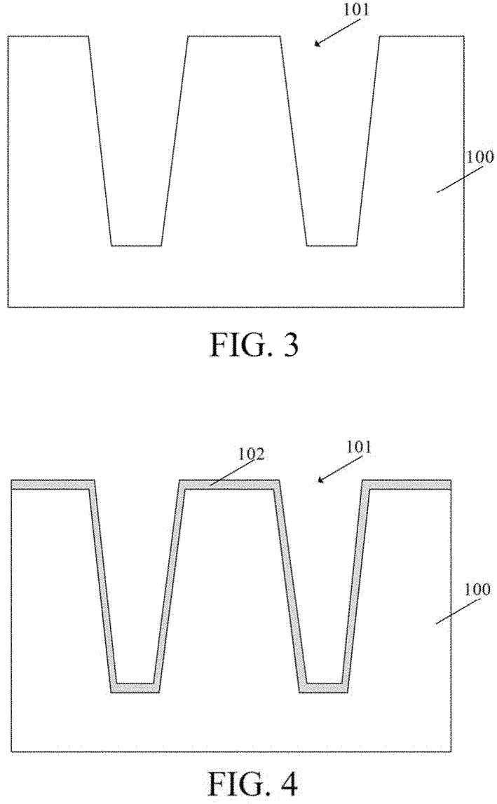

FIG. 3 to FIG. 8 are combined to illustrate schematic structural diagrams of various steps of one form of a formation method of a semiconductor structure according to implementations of the present disclosure.

As shown in FIG. 3, a substrate (not marked) is provided for use as a basis for subsequent processes. A plurality of devices to be connected is formed in the substrate.

In some implementations, a material of the substrate is silicon. In other implementations, the material of the substrate may be other materials such as germanium, silicon germanide, silicon carbide, gallium arsenide or indium gallide, and the initial substrate may be other types of substrates such as a silicon substrate on an insulator or a germanium substrate on an insulator.

In some implementations, the device to be connected is a transistor, which may be a planar transistor or a fin field effect transistor.

In other implementations, the device to be connected may be other devices such as a capacitor or an inductor.

As shown in FIG. 3, a dielectric layer 100 is formed on the substrate for isolating adjacent devices.

The dielectric layer 100 is an interlayer dielectric layer, and the material of the dielectric layer 100 is an insulating material. In some implementations, the material of the dielectric layer 100 is SiOCH.

In other implementations, the material of the interlayer dielectric layer may also be a dielectric material such as silicon nitride or silicon oxynitride, amorphous carbon or diamond-like carbon (DLC).

In order to reduce the parasitic capacitance of the contact hole plug, the material of the dielectric layer 100 may be a low-K or ultra-low-K insulating material. The low-K insulating material described herein refers to an insulating material having a dielectric constant of less than 3, and the ultra-low-K insulating material refers to an insulating material having a dielectric constant of less than 2.0.

The dielectric layer 100 may also be a porous low-K dielectric material. In order to achieve a lower dielectric constant, it is generally possible to use a material having a lower dielectric constant and introduce porosity into the material. Since the dielectric constant of air is specified to be 1, the dielectric constant can be lowered.

In some implementations, the dielectric layer 100 may be generated by chemical vapor deposition or physical vapor deposition.

It is to be noted that after forming a dielectric layer 100 and before forming a contact hole 101, the formation method further includes: forming a mask on the dielectric layer 100, where an opening is formed in the mask for patterning the dielectric layer 100 to form a contact hole.

Specifically, the material of the mask is at least one of TEOS, TiN or SiOC.

With continued reference to FIG. 3, a contact hole 101 is formed in the dielectric layer 100 for accommodating a conductive material to form a conductive plug.

Specifically, the contact hole 101 corresponds to the position of the device to be connected, and exposes a portion to be connected to the device to be connected.

In an actual process, the contact hole 101 may be formed by a dry etching process. The dry etching mode is beneficial to improve the etching efficiency of forming the contact hole 101, and the dry etching process has the characteristics of anisotropic etching and is thus also beneficial to improve the appearance quality of the contact hole 101.

After the dry etching process, a cleaning process is also performed on the contact hole 101 for removing by-products formed in the contact hole 101 by the dry etching process, thereby improving the formation quality of the contact hole plug.

Referring to FIG. 4 to FIG. 6, a seed layer 110 is formed on a bottom and sidewall of the contact hole 101, the thickness of the seed layer 110 on the bottom of the contact hole 101 being greater than that of the seed layer on the sidewall of the contact hole 101.

The thickness of the seed layer 110 on the bottom of the contact hole 101 is greater than the thickness of the seed layer on the sidewall of the contact hole 101, so that when a conductive plug is formed in the contact hole 101, since the thickness of the seed layer 110 on the bottom of the contact hole 101 is large, a conductive material is relatively easy to nucleate on the thicker seed layer. Therefore, the growth rate of the conductive material on the bottom of the contact hole 101 is high, even if an opening of the contact hole 101 is small, the conductive material on the bottom of the contact hole 101 has reached a large thickness before the conductive material contacts the sidewall of the contact hole 101 to seal the opening, thereby achieving complete filling in the contact hole 101, so that the formation probability of a hole can be reduced, and the formation quality of the conductive plug can be improved, thereby improving the reliability of an electrical connection between the conductive plug and an external circuit.

As shown in FIG. 4, in embodiments and implementations of the present disclosure, before forming the seed layer 110, a diffusion barrier layer 102 is also formed on the bottom and sidewall of the contact hole 101 for preventing metal diffusion.

Specifically, the diffusion barrier layer 102 includes one or more of TaN, Ta, TiN, Ti, or WC.

It is to be noted that if the thickness of the diffusion barrier layer 102 is too large, the diffusion barrier layer 102 occupies a large space on the bottom and sidewall of the contact hole 101, thereby affecting the subsequent formation of a seed layer 105 and a contact hole plug. If the thickness of the diffusion barrier layer 102 is too small, the effect of reducing, by the diffusion barrier layer, metal diffusion is affected. Accordingly, the diffusion barrier layer 102 has a thickness in the range of 1-5 nm.

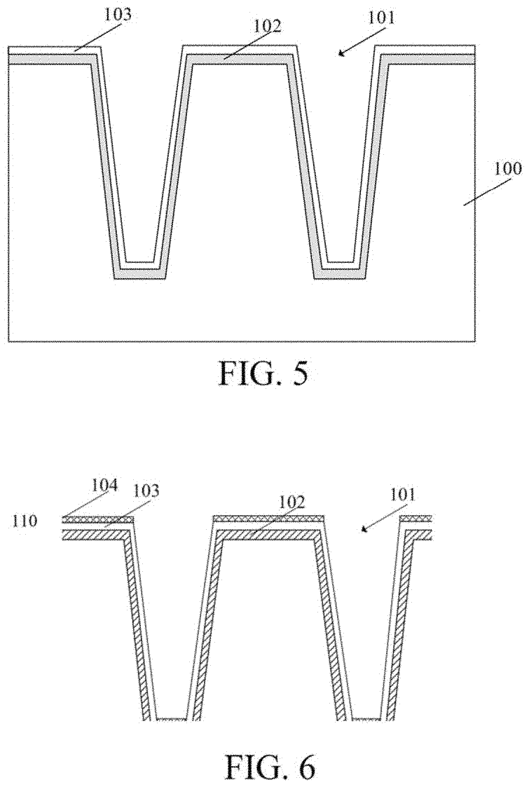

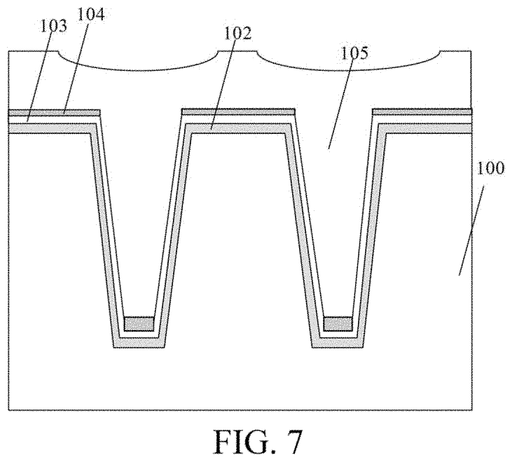

As shown in FIG. 5 and FIG. 6, a seed layer 110 is formed on the bottom and sidewall of the contact hole 101 on which the diffusion barrier layer 102 is formed.

In some implementations, the seed layer 110 includes two film layers: a first seed layer 103 and a second seed layer 104. The thickness of the first seed layer 103 on the bottom of the contact hole 101 is close to that of the first seed layer on the sidewall of the contact hole, and the thickness of the second seed layer 104 on the bottom of the contact hole 101 is greater than that of the seed layer on the sidewall of the contact hole 101. Therefore, the overall thickness of the seed layer 110 on the bottom of the contact hole 101 is greater than that of the seed layer on the sidewall of the contact hole 101.

In other implementations, the seed layer 110 may also be a single-layer structure, or the seed layer 110 may also be a multi-layer structure consisting of more than two layers.

As shown in FIG. 5, a first seed layer 103 is formed on a bottom and sidewall of the contact hole 110 by a chemical vapor deposition process.

Since the step coverage of the chemical vapor deposition process is good, the thickness of the first seed layer 103 formed by the chemical vapor deposition process on the bottom of the contact hole 110 and the thickness of the first seed layer on the sidewall of the contact hole 110 are uniform.

It is to be noted that the chemical vapor deposition process forms the first seed layer 103 on the surface of the dielectric layer 100 in addition to the first seed layer 103 on the bottom and sidewall of the contact hole 110. By means of the chemical vapor deposition process of some implementations, the thickness on the bottom and sidewall of the contact hole 110 is not less than 80% of the thickness on the surface of the dielectric layer 100. Thus, the chemical vapor deposition process has better step coverage, so that more materials can be formed inside the contact hole 110, thereby ensuring the formation of the first seed layer 103 of a certain thickness on the bottom and sidewall of the contact hole 110.

In some implementations, by forming the first seed layer 103, a continuous film-forming seed layer material is also formed on the sidewall of the contact hole 110, so that a conductive material may also be formed on the sidewall of the contact hole 110 during the subsequent electroplating process.

In some implementations, the material of the first seed layer 103 is cobalt or ruthenium.

If the thickness of the first seed layer 103 is too large, the proportion of the first seed layer 103 in the entire seed layer 110 is large, so that the proportion of the second seed layer in the entire seed layer is reduced, thereby reducing a difference between the thickness of the seed layer 110 on the bottom of the contact hole and the thickness of the seed layer on the sidewall, and easily affecting the effect of reducing the formation of a hole. Accordingly, if the thickness of the first seed layer 103 is too small, the difference between the thickness of the seed layer 110 on the bottom of the contact hole and the thickness of the seed layer on the sidewall is increased, and the growth rate of the conductive plug located on the bottom of the contact hole is easily made too high, resulting in waste of materials. Accordingly, the first seed layer 103 has a thickness in the range of 1-5 nm.

As shown in FIG. 6, a second seed layer 104 is formed on the first seed layer 103 by a radio frequency physical vapor deposition process.

The radio frequency physical vapor deposition process has the characteristics of strong ionization. Under the action of a strong electric field, ions are more likely to accumulate on the bottom of the contact hole, so the formation rate of the second seed layer 104 on the bottom of the contact hole is higher. Therefore, the thickness of the second seed layer 104 on the bottom of the contact hole is greater than that of the second seed layer 104 on the sidewall of the contact hole.

It is to be noted that the thickness of the second seed layer 104 on the bottom of the contact hole 101 is at least twice the thickness of the second seed layer 104 on the sidewall. Thus, when the conductive material is formed in the contact hole 101, compared with the growth rate of a conductive material on the sidewall of the contact hole, the growth rate of the conductive material on the bottom of the contact hole is high enough, so that the generation of holes can be avoided, the formation quality of the conductive plug can be optimized, and the reliability of an electrical connection between the conductive plug and the external circuit can be further enhanced.

Specifically, if the power of radio frequency physical vapor deposition is too large or the frequency is large, the formation rate of the second seed layer 104 on the bottom of the contact hole is too large compared with the formation rate of the second seed layer 104 on the sidewall of the contact hole. Since the formation rate of the conductive material on the bottom of the contact hole is too high, material waste is easily caused. If the power or frequency of the radio frequency physical vapor deposition is too small, the formation rate of the conductive material on the bottom of the contact hole is not high enough, and it is possible that the generation of holes cannot be completely eliminated.

Accordingly, the process conditions of the radio frequency physical vapor deposition process include: the power is 2-4 KW, and the frequency is in the range of 2-40 MHZ.

It is to be noted that in other implementations, a second seed layer 104 may also be formed on the first seed layer 103 by a direct current physical vapor deposition process.

In the direct current physical vapor deposition process, if the power is high, strong ionization may be generated. Thus, under the action of a strong electric field, ions are more likely to accumulate on the bottom of the contact hole, so the formation rate of the second seed layer 104 on the bottom of the contact hole is higher. Therefore, the thickness of the second seed layer 104 on the bottom of the contact hole is greater than that of the second seed layer 104 on the sidewall of the contact hole.

In order to achieve strong ionization, the direct current physical vapor deposition process has a power in the range of 5-15 KW.

Therefore, in the step of forming a second seed layer, a second seed layer may also be formed on the first seed layer by a direct current physical vapor deposition process, the direct current physical vapor deposition process having a power in the range of 5 KW to 15 KW.

In some implementations, the material of the second seed layer 104 is cobalt or ruthenium.

If the thickness of the second seed layer 104 is too large, the proportion of the second seed layer 104 in the entire seed layer 110 is large, so that a difference between the thickness of the seed layer 110 on the bottom of the contact hole and the thickness of the seed layer on the sidewall is increased, and the growth rate of the conductive plug located on the bottom of the contact hole is easily made too high, resulting in waste of materials. If the thickness of the second seed layer 104 is too small, the proportion of the second seed layer 104 in the entire seed layer is reduced, thereby reducing a difference between the thickness of the seed layer 110 on the bottom of the contact hole and the thickness of the seed layer on the sidewall, and easily affecting the effect of reducing the formation of a hole. Accordingly, the second seed layer 104 has a thickness in the range of 2-8 nm.

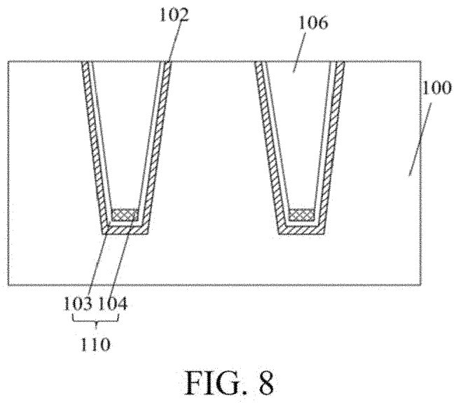

As shown in FIG. 7 and FIG. 8, a conductive plug 106 is formed in the contact hole 101 for realizing an electrical connection between the device to be connected and the external circuit.

As shown in FIG. 7, a conductive material 105 is formed in the contact hole 101 by an electroplating process. The electroplating process has a good filling property, thereby realizing a good electrical connection while ensuring that the space of the contact hole 101 is filled.

In some implementations, since the thickness of the seed layer 110 on the bottom of the contact hole 101 is greater than the thickness of the seed layer on the sidewall of the contact hole 101, the conductive material 105 easily nucleates on the bottom of the contact hole 101 to form a film during the electroplating process. Therefore, the formation rate of the conductive material 105 on the bottom of the contact hole 101 is high. Before the conductive material formed on the sidewall is not in contact, the conductive material has already filled the contact hole 101. Therefore, holes cannot be easily formed, thus improving the formation quality of the conductive plug, and improving the reliability of an electrical connection of the conductive plug.

In some implementations, the material of the conductive plug 106 is copper. A conductive material of copper is formed in the contact hole 101 by an electroplating process.

As shown in FIG. 8, excess conductive materials on the dielectric layer 100 are removed by a planarization process, and a conductive material remaining in the contact hole 101 is used as the conductive plug 106.

It is to be noted that since the mask is also formed on the surface of the dielectric layer 100 in some implementations, the planarization process also removes the mask on the surface of the dielectric layer 100 in the process of removing excess conductive materials by the planarization process.

The conductive plug 160 formed in embodiments and implementations of the present disclosure is less likely to generate holes and notches, and the reliability of the electrical connection of the conductive plug 160 can be improved.

To address the technical problem, the present disclosure also provides implementations of a semiconductor structure. With continued reference to FIG. 8, a schematic diagram of a semiconductor structure according to one form of the present disclosure is shown. The semiconductor structure includes: a substrate (not marked), a dielectric layer 100, a contact hole, a seed layer 110, and a conductive plug 106. The substrate is used as a basis for subsequent processes. A plurality of devices to be connected is formed in the substrate.

In some implementations, the material of the substrate is silicon. In other implementations, the material of the substrate may also be other materials such as germanium, silicon germanide, silicon carbide, gallium arsenide or indium gallide, and the initial substrate may also be other types of substrates such as a silicon substrate on an insulator or a germanium substrate on an insulator.

In some implementations, the device to be connected is a transistor, which may be a planar transistor or a fin field effect transistor.

In other implementations, the device to be connected may also be other devices such as a capacitor or an inductor.

The dielectric layer 100 is located on the substrate for isolating adjacent devices.

The dielectric layer 100 is an interlayer dielectric layer, and the material of the dielectric layer 100 is an insulating material. In some implementations, the material of the dielectric layer 100 is SiOCH.

In other implementations, the material of the interlayer dielectric layer may also be a dielectric material such as silicon nitride or silicon oxynitride, amorphous carbon or diamond-like carbon (DLC).

In order to reduce the parasitic capacitance of the contact hole plug, the material of the dielectric layer 100 may be a low-K or ultra-low-K insulating material. The low-K insulating material described herein refers to an insulating material having a dielectric constant of less than 3, and the ultra-low-K insulating material refers to an insulating material having a dielectric constant of less than 2.0.

The dielectric layer 100 may also be a porous low-K dielectric material. In order to achieve a lower dielectric constant, it is generally possible to use a material having a lower dielectric constant and introduce porosity into the material. Since the dielectric constant of air is specified to be 1, the dielectric constant can be lowered.

The contact hole is located in the dielectric layer 100 for accommodating a conductive material to form a conductive plug. Specifically, the contact hole 101 corresponds to the position of the device to be connected, and exposes a portion to be connected to the device to be connected.

The seed layer 110 is located on a bottom and a sidewall of the contact hole, where the thickness of the seed layer 110 on the bottom of the contact hole is greater than the thickness of the seed layer on the sidewall of the contact hole.

The thickness of the seed layer 110 on the bottom of the contact hole is greater than the thickness of the seed layer on the sidewall of the contact hole 101, so that when a conductive plug is formed in the contact hole, since the thickness of the seed layer 110 on the bottom of the contact hole is large, a conductive material is relatively easy to nucleate on the thicker seed layer. Therefore, the growth rate of the conductive material on the bottom of the contact hole is high, even if an opening of the contact hole is small, the conductive material on the bottom of the contact hole has reached a large thickness before the conductive material contacts the sidewall of the contact hole to seal the opening, thereby achieving complete filling in the contact hole, so that the formation probability of a hole can be reduced, and the formation quality of the conductive plug can be improved, thereby improving the reliability of an electrical connection between the conductive plug and an external circuit.

In some implementations, the seed layer 110 includes two film layers: a first seed layer 103 and a second seed layer 104. The thickness of the first seed layer 103 on the bottom of the contact hole 101 is close to that of the first seed layer on the sidewall of the contact hole, and the thickness of the second seed layer 104 on the bottom of the contact hole 101 is greater than that of the seed layer on the sidewall of the contact hole 101. Therefore, the overall thickness of the seed layer 110 on the bottom of the contact hole 101 is greater than that of the seed layer on the sidewall of the contact hole 101.

In other implementations, the seed layer 110 may also be a single-layer structure, or the seed layer 110 may also be a multi-layer structure consisting of more than two layers.

In some implementations, by providing the first seed layer 103, a continuous film-forming seed layer material is also formed on the sidewall of the contact hole 110, so that a conductive material may also be formed on the sidewall of the contact hole 110 when the conductive material is formed during the electroplating process.

In some implementations, the material of the first seed layer 103 is cobalt or ruthenium.

If the thickness of the first seed layer 103 is too large, the proportion of the first seed layer 103 in the entire seed layer 110 is large, so that the proportion of the second seed layer in the entire seed layer is reduced, thereby reducing a difference between the thickness of the seed layer 110 on the bottom of the contact hole and the thickness of the seed layer on the sidewall, and easily affecting the effect of reducing the formation of a hole. Accordingly, if the thickness of the first seed layer 103 is too small, the difference between the thickness of the seed layer 110 on the bottom of the contact hole and the thickness of the seed layer on the sidewall is increased, and the growth rate of the conductive plug located on the bottom of the contact hole is easily made too high, resulting in waste of materials. Accordingly, the first seed layer 103 has a thickness in the range of 1-5 nm.

It is to be noted that the thickness of the second seed layer 104 on the bottom of the contact hole 101 is at least twice the thickness of the second seed layer 104 on the sidewall. Thus, when the conductive material is formed in the contact hole 101, compared with the growth rate of a conductive material on the sidewall of the contact hole, the growth rate of the conductive material on the bottom of the contact hole is high enough, so that the generation of holes can be avoided, the formation quality of the conductive plug can be optimized, and the reliability of an electrical connection between the conductive plug and the external circuit can be further enhanced.

In some implementations, the material of the second seed layer 104 is cobalt or ruthenium.

If the thickness of the second seed layer 104 is too large, the proportion of the second seed layer 104 in the entire seed layer 110 is large, so that a difference between the thickness of the seed layer 110 on the bottom of the contact hole and the thickness of the seed layer on the sidewall is increased, and the growth rate of the conductive plug located on the bottom of the contact hole is easily made too high, resulting in waste of materials. If the thickness of the second seed layer 104 is too small, the proportion of the second seed layer 104 in the entire seed layer is reduced, thereby reducing a difference between the thickness of the seed layer 110 on the bottom of the contact hole and the thickness of the seed layer on the sidewall, and easily affecting the effect of reducing the formation of a hole. Accordingly, the second seed layer 104 has a thickness in the range of 2-8 nm.

The conductive plug 106 is located in the contact hole.

In some implementations, since the thickness of the seed layer 110 on the bottom of the contact hole 101 is greater than the thickness of the seed layer on the sidewall of the contact hole 101, the conductive material 105 easily nucleates on the bottom of the contact hole 101 to form a film during the electroplating process. Therefore, the formation rate of the conductive material 105 on the bottom of the contact hole 101 is high. Before the conductive material on the sidewall is not in contact, the conductive material has already filled the contact hole 101. Therefore, holes cannot be easily formed, thus improving the formation quality of the conductive plug, and improving the reliability of an electrical connection of the conductive plug.

In some implementations, the material of the conductive plug 106 is copper.

The semiconductor structure may further include: a diffusion barrier layer located between the bottom of the contact hole or the sidewall of the contact hole and the seed layer for preventing metal diffusion.

Specifically, the diffusion barrier layer 102 includes one or more of TaN, Ta, TiN, Ti, and WC.

It is to be noted that if the thickness of the diffusion barrier layer 102 is too large, the diffusion barrier layer 102 occupies a large space on the bottom and sidewall of the contact hole 101, thereby affecting the subsequent formation of a seed layer 105 and a contact hole plug. If the thickness of the diffusion barrier layer 102 is too small, the effect of reducing, by the diffusion barrier layer, metal diffusion is affected. Accordingly, the diffusion barrier layer 102 has a thickness in the range of 1-5 nm.

The conductive plug 160 in the semiconductor structure of the present disclosure is less likely to generate holes and notches, and the reliability of the electrical connection of the conductive plug 160 can be improved.

The semiconductor structure may be formed by the formation method of a semiconductor structure according to an embodiment of the present disclosure, or may also be formed by other formation methods of a semiconductor structure.

Embodiments and implementations of the present disclosure are disclosed above, but embodiments and implementations of the present disclosure are not limited thereto. A person skilled in the art can make various changes and modifications without departing from the spirit and scope of the embodiments and implementations of the present disclosure, and the scope of the embodiments and implementations of the present disclosure should be determined by the scope defined by the claims.

What is claimed is:

1. A formation method of a semiconductor structure, comprising:
providing a substrate;
forming a dielectric layer on the substrate;
forming a contact hole in the dielectric layer;
forming a seed layer on a bottom and a sidewall of the contact hole, where a thickness of the seed layer on the bottom of the contact hole is greater than a thickness of the seed layer on the sidewall of the contact hole; and
forming a conductive plug in the contact hole.

2. The formation method according to claim 1, wherein the step of forming a seed layer comprises:
forming a first seed layer on the bottom and the sidewall of the contact hole using a chemical vapor deposition process; and
forming a second seed layer on the first seed layer using a radio frequency physical vapor deposition process.

3. The formation method according to claim 2, wherein the radio frequency physical vapor deposition process has a power of 2 KW to 4 KW and a frequency in a range of 2 MHZ to 40 MHZ.

4. The formation method according to claim 2, wherein the thickness of the second seed layer on the bottom of the contact hole is at least twice the thickness of the second seed layer on the sidewall.

5. The formation method according to claim 2, wherein the first seed layer has a thickness in a range of 1-5 nm.

6. The formation method according to claim 2, wherein the second seed layer has a thickness in a range of 2-8 nm.

7. The formation method according to claim 1, wherein the step of forming a seed layer comprises:
forming a first seed layer on the bottom and the sidewall of the contact hole using a chemical vapor deposition process; and
forming a second seed layer on the first seed layer using a direct current physical vapor deposition process, where the direct current physical vapor deposition process has a power in a range of 5 KW to 15 KW.

8. The formation method according to claim 1, wherein a material of the seed layer is cobalt or ruthenium.

9. The formation method according to claim 1, wherein a conductive plug is formed in the contact hole by an electroplating process.

10. The formation method according to claim 1, wherein a material of the conductive plug is copper.

11. The formation method according to claim 1, further comprising:
forming, after forming the contact hole and before forming the seed layer, a diffusion barrier layer on the bottom and sidewall of the contact hole.

12. The formation method according to claim 11, wherein the diffusion barrier layer has a thickness in a range of 1-5 nm.

13. A semiconductor structure, comprising:
a substrate;
a dielectric layer located on the substrate;
a contact hole located in the dielectric layer;
a seed layer located on a bottom and a sidewall of the contact hole, where a thickness of the seed layer on the bottom of the contact hole is greater than a thickness of the seed layer on the sidewall of the contact hole; and
a conductive plug located in the contact hole.

14. The semiconductor structure according to claim 13, wherein the seed layer comprises:
a first seed layer located on the bottom and the sidewall of the contact hole; and
a second seed layer located on the first seed layer, where a thickness of the second seed layer on the bottom of the contact hole is greater than a thickness of the second seed layer on the sidewall of the contact hole.

15. The semiconductor structure according to claim 14, wherein the thickness of the second seed layer on the bottom of the contact hole is at least twice the thickness of the second seed layer on the sidewall.

16. The semiconductor structure according to claim 14, wherein the first seed layer has a thickness in a range of 1-5 nm.

17. The semiconductor structure according to claim 14, wherein the second seed layer has a thickness in a range of 2-8 nm.

18. The semiconductor structure according to claim 13, wherein a material of the seed layer is cobalt or ruthenium.

19. The semiconductor structure according to claim 13, wherein a material of the conductive plug is copper.

20. The semiconductor structure according to claim 13, further comprising:
a diffusion barrier layer located between the bottom of the contact hole or the sidewall of the contact hole and the seed layer.
